(19) United States
(12) Patent Application Publication
(10) Pub. No.: US 2011/0124144 A1
(43) Pub. Date: May 26, 2011

(54) SUBSTRATE PROCESSING SYSTEM AND SUBSTRATE PROCESSING METHOD

(75) Inventors: Hermann Schlemm, Jena (DE); Matthias Uhlig, Lugau (DE)

(73) Assignee: ROTH & RAU AG, Hohenstein-Ernstthal (DE)

(21) Appl. No.: 13/055,745

(22) PCT Filed: Mar. 17, 2009
(86) PCT No.: PCT/DE2009/000383

§ 371 Date: Jan. 25, 2011

(51) Int. Cl. H01L 31/18; C23F 1/08; C23F 1/00; C23F 1/12; H01L 21/465

(52) U.S. Cl. 438/57; 156/345.29; 156/345.26; 216/37; 438/706; 257/E31.001; 257/E21.485

(57) ABSTRACT

A substrate processing apparatus includes an evacuatable process chamber configured to receive a substrate carrier having at least one substrate, a plasma generating module, a gas feed, a gas discharge and a vapor etching module provided in the process chamber. A substrate processing method includes introducing a substrate carrier including at least one substrate into an evacuatable process chamber, generating a plasma in a plasma process using a plasma generating module in a gas or a gas mixture, performing a vapor etching of the at least one substrate before, after or alternatingly with the plasma process and performing at least one of a coating, etching, surface modification and cleaning of the substrate.

### CROSS REFERENCE TO RELATED APPLICATIONS

This application is a U.S. National Phase application under 35 U.S.C. §371 of International Application No. PCT/DE2009/000383, filed on Mar. 17, 2009. The International Application was published in German on Sep. 23, 2010 as WO 2010/105585 A1 under PCT Article 21 (2).

### FIELD

The present invention relates to a substrate processing apparatus including at least one evacuatable process chamber into which at least one substrate carrier with at least one substrate can be introduced, and a substrate processing method.

### BACKGROUND

Substrate processing apparatuses that including an evacuatable process chamber may also have a plasma generating module, a gas feed and a gas discharge. Corresponding substrate processing methods, in which a substrate carrier with a substrate is introduced into the evacuatable process chamber may also include generating a plasma in a plasma process by means of a plasma generating module in a gas or a gas mixture and performing a coating, etching, surface modification and/or cleaning of the substrate. Such apparatuses and methods are used in microelectronics and micromechanics for performing plasma coating, plasma etching, plasma oxidation, surface hydrophilizing and hydrophobizing and plasma cleaning processes for diverse applications. Inter alia, such apparatuses and methods are also used in the production of solar cells.

The solar cell industry is currently undergoing dynamic development. While record solar cells based on silicon with an efficiency of 24.7% were able to be produced as early as in 2000, silicon solar cells from mass production achieve efficiencies of 16% to 18% for monocrystalline solar cells and 14% to 16% for multicrystalline cells.

Standard solar cell technology is currently based on silicon wafers having a thickness of 200 μm to 400 μm. After the wafers have been produced it is beneficial to remove sawing damage from the surface, which corresponds to the removal of a silicon layer approximately 5 μm thick. Mode solar cells are additionally provided with surface textures, often on the basis of the structures predetermined by the sawing damage. This texture is intended to increase the coupling-in of light, particularly in the case of oblique incidence of light. The reflection is thereby reduced from approximately 35% to approximately 10%.

The removal of the sawing damage and the texture production are effected by means of etching. The prevailing method here is based on wet-chemical processes in batch or continuous (inline) methods. The alkaline etching bath using KOH that has been customary hitherto predominantly for monocrystalline substrate material operates in a manner dependent on the crystal direction, and only a flat texture therefore arises on multicrystalline wafers. In order to achieve a sufficient texture effect, recently use has also been made of acidic etching baths, for example predominantly comprising HF (hydrofluoric acid) and HNO₃, in some instances also additionally comprising CH₃COOH. Greatly textured surfaces thus arise on multicrystalline wafers.

During the production of solar cells, the wafer material is predoped in such a way that it is p-conducting, for example. In order to produce a pn junction, an n-conducting doping has to be applied. This is done by means of phosphorus diffusion, wherein the phosphorus diffuses into the wafer material to a depth of approximately 0.5 μm.

For the purpose of phosphorus diffusion, use is made of oxide layers, for example, such as an approximately 60 nm to 100 nm thick PSG (phosphosilicate glass; (SiO₂)₁₋ₓ(P₂O₅)_{y}) layer, which is deposited onto the p-conducting wafer. At a specific process temperature, phosphorus diffuses into the wafer material from the PSG layer. The PSG layer is subsequently removed again before an antireflection layer, such as Si₃N₄, for example, is applied to the wafer.

The removal of the PSG layer is usually effected by means of wet-chemical HF (hydrofluoric acid) etching. Wet etching is an isotropic etching method having the advantage of a very high etching selectivity. Typically both sides of the wafer are treated during wet etching. A treatment with 2% strength HF is customary for untextured solar cell wafers.

New solar cell concepts with a textured front side in many cases respectively necessitate only a treatment of the front side, and so complicated readjustments in the wet-chemical technology which allow a single-sided etch are required for wet-chemical etching. Moreover, the wet chemistry consumes a relatively large amount of etching solution and it is relatively difficult, during etching, to keep the process stable through constant alteration of the process chemistry and the enrichment of the etching bath with reaction products and contaminants. Furthermore, the spent etching solutions pose disposal problems.

At the present time, therefore, developments are being implemented which can result in the wet-chemical methods being superseded by plasma-based dry methods. In this case, a plasma is used to produce reactive particles, e.g. reactive ions such as CF₃⁺ or reactive radicals F^{*}, O^{*} or CF₃^{*}; which manifest chemical etching effects on the surface. Reactive ion etching (RIE) is used in microelectronics, which has a good selectivity, a high anisotropy and a simultaneous passivation of the sidewall that does not extend parallel to the substrate surface by means of polymer formation from the etching gases by means of plasma polymerization.

The oxide etching by means of plasma is predominantly effected by means of fluorine, such as e.g. in the reaction

SiO₂+CF₄→SiF₄+CO₂.

A microwave plasma assisted reaction of the gases NH₃ and NF₃ to form NH₄⁺, may also be carried out, which etches SiO₂ selectively with respect to silicon.

The plasma-chemical etching of oxides on silicon is sufficiently selective like wet-chemical etching. However, the anisotropy of the method is unfavorable for the acidically textured surfaces employed in new solar cell concepts in the case of multicrystalline wafers. Only those locations with oxides which are situated perpendicular to the impinging reactive particles are etched well. All perpendicular regions and cavities which are already present in the acidic texture are not etched away sufficiently on account of the high degree of anisotropy.

Especially in the case of inline methods for applying P-containing substances, an excessively high phosphorus concentration remains after the diffusion process and the removal of the PSG layer in the wafer surface. This layer, the so-called “dead layer”, having a thickness of approximately 20 nm to approximately 50 nm, is supersaturated with charge carriers and is therefore not fully electrically activatable. The “dead layer” should preferably also be removed. The document WO 2008/943 827 proposes, for removing the “dead layer” before the silicon nitride deposition, a dry plasma process using a C₂F₆—O₂ mixture as etching gas. In this case, too, on account of the high anisotropy of the plasma etching method, problems arise in the case of acidically textured surfaces, such that either the “dead layer” is only removed non-uniformly or significantly more material is etched than is necessary to remove the region having an excessively high phosphorus concentration.

Furthermore, there are devices and methods for etching silicon wafers, which use vaporous hydrofluoric acid/water mixtures for etching SiO₂. Thus, by way of example, the document DE 299 15 696 U1 describes an etching apparatus for HF vapor etching in which silicon wafers microstructured with an SiO₂ sacrificial layer are etched by means of HF vapor. For the HF vapor etching, the known apparatus has separate vapor etching modules which are arranged as a cluster on a gripper station and in each of which a wafer can be etched. In order to remove organic materials or contaminations from the wafer surfaces before the HF etching, in the case of the method described in the document DE 299 15 696 U1, the wafers are cleaned beforehand in an oxygen plasma stripper.

Owing to the large number of process chambers and the plasma cleaning required before the HF vapor etching, the method described in the document DE 299 15 696 U1 is relatively laborious and not very productive. As a result, the HF vapor etching apparatus yields only a low throughput of etched wafers.

### SUMMARY

Therefore, an aspect of the present invention is to provide a substrate processing apparatus and a substrate processing method with which even greatly surface-textured substrates can be etched isotropically with relatively high throughput and quality.

In an embodiment, the present invention provides a continuous substrate processing apparatus including an evacuatable process chamber configured to receive a substrate carrier having at least one substrate, a plasma generating module, a gas feed, a gas discharge and a vapor etching module provided in the process chamber. A substrate processing method includes introducing a substrate carrier including at least one substrate into an evacuatable process chamber, generating a plasma in a plasma process using a plasma generating module in a gas or a gas mixture, performing a vapor etching of the at least one substrate before, after or alternatingly with the plasma process and performing at least one of a coating, etching, surface modification and cleaning of the substrate.

### BRIEF DESCRIPTION OF THE DRAWINGS

Exemplary embodiments of the present invention, and the construction, function and advantages thereof are explained in greater detail below with reference to the schematic representations drawings, in which:

FIG. 1 shows a diagrammatic sketch of a substrate processing apparatus;

FIG. 2 shows a substrate support suitable for front- and/or rear-side treatment of a substrate;

FIG. 3 shows another embodiment of a substrate support for a front-side treatment ;

FIG. 4 shows another embodiment of a substrate support, in the form of a hook support;

FIG. 5 shows a diagrammatic sketch of a gas metering system which can be used in a substrate processing apparatus;

FIG. 6 shows a diagrammatic sketch of an etching vapor generating system which can be used in a substrate processing apparatus;

FIG. 7 shows a diagrammatic sketch of a substrate processing apparatus with an upstream gas metering system and a downstream exhaust gas removing system;

FIG. 8 shows a substrate processing apparatus with a plurality of process chambers;

FIG. 9 shows a substrate processing apparatus in the form of a continuous apparatus for a rear-side treatment of solar cell substrates;

FIG. 10 shows a substrate processing apparatus in the form of a continuous apparatus for a front-side treatment of solar cell substrates;

FIG. 11 shows a substrate processing method for PSG etching on a substrate front side;

FIG. 12 shows a substrate processing method for PSG and emitter rear-side etching of a substrate;

FIG. 13 shows a substrate processing method for removing a “dead layer” for production of a solar cell wafer;

FIG. 14 shows a substrate processing method for removing a “dead layer” before a silicon nitride deposition for solar cell production;

FIG. 15 shows another substrate processing method for removing a “dead layer” for producing a solar cell wafer;

FIG. 16 shows another substrate processing method for removing a “dead layer” before a silicon nitride deposition for producing solar cells; and

FIG. 17 shows a substrate processing method for air oxide removal before an a—Si PECVD deposition step during solar cell production.

### DETAILED DESCRIPTION

In an embodiment of the invention, the substrate processing apparatus makes it possible to be able to carry out both a plasma process and a vapor etching on the at least one substrate within one process chamber. In this case, a wide variety of plasma treatment and vapor etching steps come into consideration, which can be performed in different sequences in the process chamber. Accordingly, the substrate processing apparatus can be used for a wide variety of applications, wherein the combined process sequence of plasma and vapor etching steps results in a high efficiency of the substrate processing apparatus since time-consuming substrate handling steps between the plasma and vapor etching steps are not required here.

By means of this substrate processing apparatus, the advantages of plasma steps can be combined with the advantages of vapor etching steps in a suitable manner for optimum substrate processing. This is surprisingly possible despite the completely different requirements made of plasma and vapor etching processes.

In an embodiment of the present invention, the vapor etching module is an HF vapor etching module. The HF vapor etching allows, for example, isotropic etching of silicon dioxide with a high etching selectivity with respect to silicon. The HF vapor etching module provided according to the invention is thus suitable, in particular, for etching oxide or PSG on greatly textured surfaces of silicon solar cell wafers, wherein the selectivity of the chemical vapor phase etching using HF is comparable with wet-chemical HF etching processes. In contrast to wet etching processes, the HF vapor etching module provided according to the invention establishes significantly simplified single-sided etching of substrates. Since a new, unused etching chemical is constantly provided for the etching process, there is no change in the etching chemical over time and no enrichment with reaction products and contaminants which, in the case of wet-chemical processes, requires constant readjustment or complete renewal of the etching baths. Furthermore, significantly less etching solution is consumed by a vapor etching step than in a wet etching step, with the result that a more cost-effective and more environmentally friendly etching process can be made available with the substrate processing apparatus according to the invention. Precisely in the case of the currently continuously increasing production numbers for solar cell wafers this is particularly significant since the requirement for HF on the part of solar cell manufacturers can thereby be reduced overall, as a result of which the need to transport HF from the chemical manufacturer to the solar cell manufacturer can also be reduced and routes can thus be relieved.

It is particularly expedient if the substrate processing apparatus has an etching gas-resistant internal lining and an etching gas-resistant substrate carrier. By virtue of these structural features, an apparatus having a particularly long lifetime can be made available, wherein diverse etching gases, both in plasma and in vapor etching steps, can be employed.

In accordance with an embodiment of the present invention, the vapor etching module may have a gas spray having a plurality of gas outlets distributed over an area of the process chamber. This affords the possibility of being able to vapor-etch a plurality of substrates, distributed over the area of the process chamber.

In an embodiment, the vapor etching module is coupled to an etching vapor supply unit. By means of the etching vapor supply unit, in a manner dependent on the respective process step, etching vapor of the required composition can be made available to the vapor etching module continuously and/or in a temporally metered manner.

The etching vapor supply unit may have a gas metering system and/or an etching vapor generating system having a temperature-regulated space which has a liquid etching substance and through which at least one carrier gas flow is passed. By means of the gas metering system, a respective etching vapor with a further etching vapor and/or one or a plurality of carrier gases can be mixed in a metered manner and fed to the process chamber by means of the etching vapor supply unit. Furthermore, the liquid etching substance in the temperature-regulated space can be heated in such a way that an etching vapor is formed, which can be entrained by the carrier gas flow and conducted into the process chamber via the etching vapor supply unit.

In an embodiment of the present invention, the plasma generating module has at least one suppliable electrode embodied in a planar fashion in the process chamber. In this case, a plurality of individual or electrically interconnected electrodes can also be provided. By virtue of the planar embodiment of the at least one electrode provided, a plurality of substrates can be processed simultaneously in the process chamber. In this case, the at least one electrode can be provided above and/or below the substrates for a front-side and/or a rear-side treatment of the substrates. The at least one electrode can have a likewise suppliable counterelectrode. However, the housing of the process chamber can also serve as a counterelectrode, said housing then typically having a ground connection.

In accordance with another embodiment of the present invention, the substrate carrier has at least one substrate support having a planar supporting region for a circumferential region of the at least one substrate. By virtue of the planar supporting region, a substrate can be applied to the substrate support in such a way that, during a substrate front-side plasma treatment, the plasma does not attack the substrate rear side, or attacks it only to a negligibly small extent. Furthermore, the planar supporting region makes it possible to make contact with the substrate, such that the latter can be grounded during a plasma treatment, for example.

In one specific configuration of the invention, the substrate support has an opening within the supporting region. This allows, besides the front-side treatment, additionally a rear-side treatment of the substrate in the process chamber, wherein plasma and/or etching vapor can pass through the opening to the substrate rear side.

In accordance with an embodiment of the present invention, at least one internal volume reducing component is provided in the process chamber. The internal volume of the process chamber can thereby be reduced in such a way that less process gas and/or etching vapor is required in the process steps performed in the process chamber, such that procedures can be carried out particularly cost-efficiently.

The substrate processing apparatus may have a continuous apparatus. Consequently, in the substrate processing apparatus, a plurality of process chambers can be coupled to one another, through which substrates can pass successively. It is thereby possible to be able to process a multiplicity of process steps or an entire technological process sequence continuously in the substrate processing apparatus.

The substrate processing apparatus can be an apparatus for producing solar cells, in which it is possible in an effective manner to be able to etch even greatly textured solar cell wafers.

In an embodiment of the present invention, the process chamber has a heating and/or cooling device, or is coupled to a heating and/or cooling device. By means of the heating and/or cooling device, vapor etching steps performed in the process chamber, in particular, can be controlled particularly well by means of heating and/or cooling of the process chamber interior and thus of the temperature of the etching vapor in the process chamber.

In an embodiment, the present invention also provides a substrate processing method, wherein at least one substrate carrier with at least one substrate is introduced into at least one evacuatable process chamber and, in the process chamber, a plasma is generated by a plasma process by means of a plasma generating module in a gas or a gas mixture and a coating, etching, surface modification and/or cleaning of the substrate is thus performed, and wherein a vapor etching of the at least one substrate is carried out in the process chamber before and/or after and/or alternately with the plasma process.

The substrate processing method makes it possible to perform both a plasma treatment and a vapor etching of the at least one substrate in a single process chamber. Consequently, plasma treatment steps can be performed directly before a vapor etching step, and vice versa, without the substrate having to leave the process chamber. This has the advantage that the substrate properties set by the preceding process step in the process chamber are present unchanged as a basis for the subsequent process step on the substrate in the process chamber, as a result of which the quality and effectiveness of the process steps and therefore also the quality of the substrates produced by means of the method according to the invention can be significantly improved. Complicated intermediate handling steps and apparatus parts required therefor can be omitted. Shorter substrate passage times, a higher substrate throughput, a smaller space requirement and reduced costs for the apparatus technology are the consequence.

The vapor etching can be carried out using HF-containing vapor. By means of the HF etching vapor, it is possible, in particular, for silicon dioxide and SiO₂-containing materials, such as phosphosilicate glass, to be etched isotropically and with high selectivity with respect to silicon in a manner comparable with a wet etching method. Moreover, the HF vapor etching method is suitable, in particular, for a single-sided etching of substrates. This is particularly expedient for a silicon oxide or PSG etching of acidically textured solar cell wafers in which even deeper regions and/or regions covered by cavities or the like can be reliably etched in the HF vapor etching step. Furthermore, the proposed embodiment of the method according to the invention affords the advantage that significantly less HF than in a wet-chemical method is consumed in the HF vapor etching step. Moreover, the HF concentration in the HF vapor can easily be controlled by simple feeding and discharging of the HF-containing vapor in order to achieve optimum etching results.

In an embodiment, the substrate processing method according to the invention is used to process substrates for producing solar cells. Particularly in the case of solar cell wafers there is manifested, precisely in the case of new technologies, a constantly increased demand for single-side technologies which make it possible to be able to etch silicon oxide and PSG reliably even on greatly textured surfaces. Moreover, in solar cell production, the substrates used are becoming thinner and thinner, which makes wet etching more and more difficult since the thin substrates float in the etching bath and therefore cannot be reliably etched. With this method, such substrates can readily be etched isotropically from one side. Moreover, the procedure ensures a high substrate throughput, with the result that a large number of solar cell wafers can be produced in short process times with reduced apparatus outlay.

In one embodiment of the method according to the invention, PSG is etched from a front side of the substrate in an HF vapor etching step in the at least one process chamber, wherein a plasma oxidation of one or more surface layers of the substrate is effected in a subsequent process step in the process chamber. Consequently, in the HF vapor etching step, which enables single-sided isotropic and selective etching, the PSG can be reliably removed from the front side of the substrate, wherein the etched substrate surface can immediately be covered with oxide by means of the plasma oxidation in the subsequent process step. A defined, cleaned surface of the substrate can be provided in this way. Moreover, contaminants and/or structural defects at the substrate surface can be buried by the oxide produced in the plasma oxidation step.

In a further embodiment of the present invention, PSG is etched from a rear side of the substrate in an HF vapor etching step in the process chamber or a further process chamber and an emitter rear-side etching of the substrate is performed in a subsequent process step in the process chamber in a plasma etching step. With this process implementation it is possible, in the same chamber, to remove firstly PSG and then the parasitic emitter region from the rear side of a solar cell wafer.

In an embodiment of the substrate processing method according to the invention, a vapor etching step using a vapor mixture containing KOH and HCl for etching metal ions from the substrate is carried out after the HF vapor etching step for etching the PSG in the process chamber. In this way, elimination of metal residues on the surface can be performed before the plasma oxidation of the substrate front side and/or before the plasma etching step for the emitter rear-side etching of the substrate.

In another embodiment of the substrate processing method according to the invention, in the process chamber or a further process chamber, an O₂ plasma cleaning is carried out before the HF vapor etching step and/or after the emitter rear-side etching of the substrate. The O₂ plasma cleaning before the HF vapor etching step makes it possible to remove organic contaminants, and so the subsequent HF vapor etching can be effected more easily. Since organic polymers arise during the emitter rear-side etching of the substrate in a plasma etching step using fluorine-containing gases, a residue-free surface can be provided by means of the O₂ plasma cleaning after the emitter rear-side etching of the substrate, said surface being particularly well prepared for the coating with an antireflection layer in the production of solar cell wafers, by way of example.

In accordance with an embodiment of the substrate processing method according to the invention, a plasma oxidation of one or more surface layers of the substrate is effected in the process chamber or a further process chamber and an HF vapor etching of the oxidized surface layers is effected in a subsequent process step in the process chamber. By means of the plasma oxidation and the subsequent HF vapor etching, the surface layers of the substrate can be removed and the substrate can thus be cleaned. In this way, by way of example, a surface of a silicon substrate can be prepared for a deposition of an a—Si PECVD layer.

If the plasma oxidation and the HF vapor etching are performed alternately a number of times, the cleaning effect can additionally be improved. Moreover, with this alternating process, the “dead layer” can be effectively removed from a silicon substrate which has been doped with phosphorus by means of PSG in previous process steps and from which the PSG has been etched.

If the last step of the alternating process sequence is a plasma oxidation, the substrate is particularly well prepared for a subsequent silicon nitride deposition since the nitride adheres well on the oxide. The silicon nitride layer can be used for example as an antireflection layer on a solar cell wafer.

In another embodiment of the substrate processing method according to the invention, an O₂ plasma cleaning is in the process chamber or a further process chamber and a surface layer of the substrate is etched subsequently in the process chamber in a vapor etching step using HF-containing vapor and reactive oxygen. By means of the O₂ plasma cleaning, the surface of the substrate is firstly freed of organic contaminants, in particular, such that it is particularly well prepared for the subsequent vapor etching step in the process chamber. A mixture containing HF-containing vapor and reactive oxygen such as ozone, for example, is used in the vapor etching step. The substrate surface is oxidized by the reactive oxygen, wherein almost at the same time the oxidized layers are etched again from the silicon substrate by means of the HF-containing vapor. By means of a suitable setting of the concentration of the HF and of the reactive oxygen, it is possible to control the process in the process chamber such that, for example, a “dead layer” can be suitably removed from a silicon substrate doped with phosphorus by means of PSG. Owing to the use of the HF vapor, in this case the “dead layer” can be reliably removed even from greatly textured silicon substrates. This process variant can furthermore be used for cleaning and for front- and rear-side layer removal in the case of a substrate.

If, in the vapor etching step using HF-containing vapor and reactive oxygen, at the end of the vapor etching step, reactive oxygen is fed to the process chamber to an intensified degree, the substrate thus processed has an oxide layer at the surface at the end of the process. This is suitable, in particular, for a subsequent silicon nitride deposition, for example for producing an antireflection layer on a solar cell wafer.

After the vapor etching step using HF-containing vapor and reactive oxygen, it is also possible to carry out a plasma oxidation in the process chamber, which gives rise to an oxide layer on the substrate surface. This is a suitable basis for a subsequent silicon nitride deposition, for example for producing an antireflection layer for a solar cell wafer.

In accordance with a further option of the substrate processing method according to the invention, air oxide is removed from a front side and/or a rear side of a silicon substrate in an HF vapor etching step in the process chamber or a further process chamber, wherein an O₂ plasma cleaning of the silicon substrate is carried out in this process chamber before and/or after the HF vapor etching step. This process is suitable particularly for high-quality air oxide removal, for example before an a—Si PECVD layer deposition for producing a pn junction for a solar cell wafer.

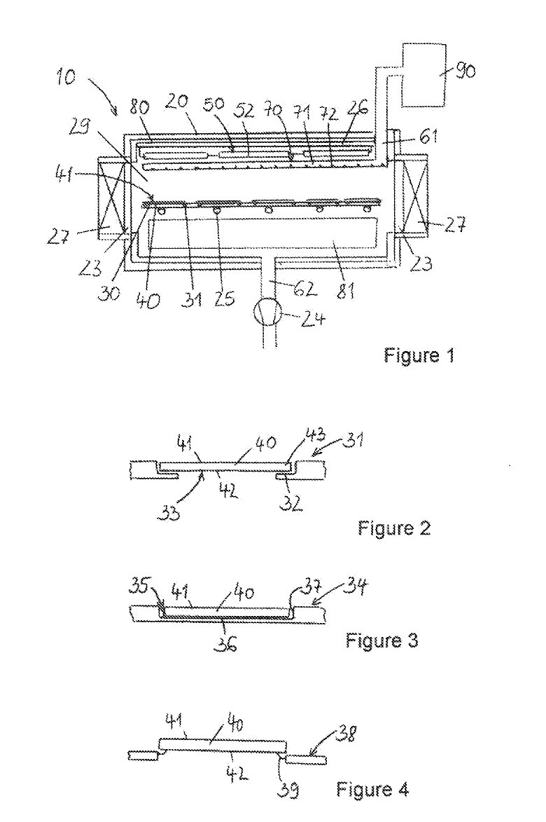

FIG. 1 schematically shows a diagrammatic sketch of a substrate processing apparatus 10 comprising an evacuatable process chamber 20. The individual elements of the process chamber 20 which are illustrated in FIG. 1 merely illustrate their functional principle and are therefore not depicted true to scale and can also be situated at other positions in or on the process chamber 20.

The process chamber 20 is substantially formed from high-grade steel or structural steel and has an internal lining 80 composed of an etching gas-resistant material. In the exemplary embodiment shown in FIG. 1, the internal lining 80 is inert toward HF and formed for example from graphite, pure Al₂O₃ or teflon-like polymers. The internal lining 80 can be formed by an etching gas-resistant chamber coating or else by plates mounted on the internal wall of the chamber.

The process chamber 20 has both at its entrance and at its exit in each case a gate 27 with a valve flap 23 which can be opened and closed and through which an interior 29 of the process chamber 20 is accessible from the outside and via which the process chamber 20 can be connected to other process chambers of the substrate processing apparatus 10. The process chamber 20 furthermore has at least one gas feed 61, at least one gas discharge 62 with a vacuum pump 24 and a heating and/or cooling device 26.

In the exemplary embodiment shown in FIG. 1, a plasma generating module 50 having one or a plurality of electrodes 52 embodied in planar fashion is provided in an upper region. Electrical contact is made with each of the electrodes 52, wherein the electrodes 52 can each be supplied individually with a potential or else be interconnected.

In other embodiment of the present invention, the plasma generating module 50 can also have one or a plurality of other plasma generating elements such as microwave bars, for example. Alternatively, it is also conceivable for the plasma generating module 50 to have an ICP (Inductive Coupled Plasma) module, wherein the actual plasma source can also be situated outside the process chamber 20.

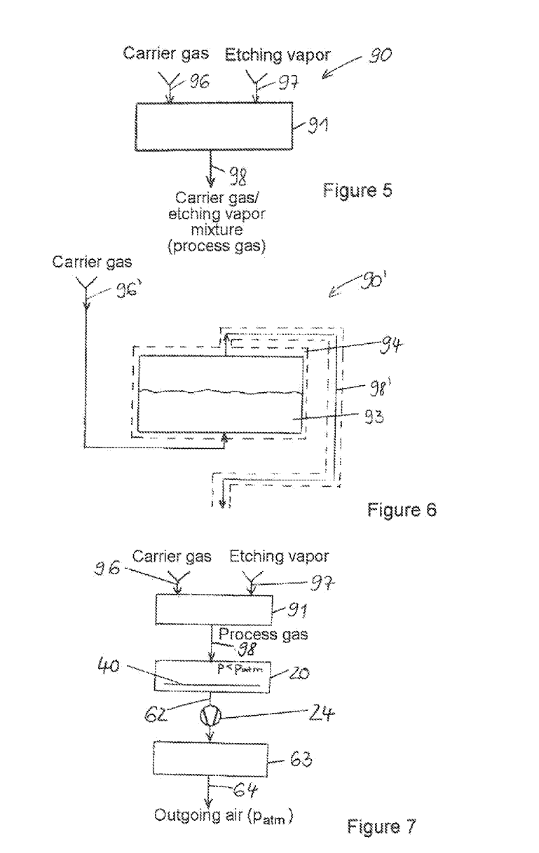

Furthermore, there is integrated in the process chamber 20 a vapor etching module 70, which, in the exemplary embodiment shown, is an HF vapor etching module, which has, in an upper region of the process chamber 20, a gas spray 71 having a plurality of gas outlets 72 distributed over an area of the process chamber 20. The vapor etching module 70 is coupled via the at least one gas feed 61 to an etching vapor supply unit 90, which is described in greater detail on the basis of examples in FIGS. 5 to 7.

At least one substrate carrier 30 with at least one substrate 40 can be introduced into the process chamber 20 via the gate 27. The substrate carrier 30 can be discharged from the process chamber 20 again via the gate 27 at the end of the process chamber 20.

The substrate carrier 30 consists of an etching gas-resistant material, preferably an HF-resistant material. In the exemplary embodiment shown, the substrate carrier 30 is formed from Al₂O₃, for example.

In the exemplary embodiment shown, the substrate carrier 30 has a plurality of substrate supports for substrates 40. Examples of possible substrate supports 31, 34, 38 are shown in FIGS. 2 to 4 and described in greater detail below.

The substrate carrier 30 is guided on transport rollers 25, which preferably likewise consist of an etching gas-resistant material or are coated with such a material.

Furthermore, an internal volume reducing component 81 is provided in the process chamber 20, below the substrate carrier 30 in the example, which component, in the exemplary embodiment shown, is formed from Al₂O₃, for example, and reduces the internal volume of the interior 29 of the process chamber 20 in such a way that, for filling the interior 29, only a correspondingly small amount—sufficient in particular for filling that part of the process chamber interior 29 which is situated above the substrates 40—of process gas or etching vapor has to be introduced into the process chamber 20.

FIG. 2 schematically shows an example of a substrate support 31 such as can be used in an embodiment of the substrate processing apparatus 10 according to the invention. The substrate support 31 has a planar supporting region 32 for a circumferential region 43 of a substrate 40. As a result, the substrate 40 can be placed at its circumference on the planar supporting region 32. The planar support can largely prevent the plasma, in a treatment of the substrate front side 41, from also reaching the substrate rear side 42. Furthermore, the planar supporting region 32 affords the possibility of making contact with the substrate 40, which can thereby be grounded in plasma processes, by way of example. The substrate support 31 has an opening 33 within the supporting region 32. A treatment of the substrate rear side 42 thereby becomes possible as well.

FIG. 3 schematically shows a further embodiment variant of a substrate support 34 such as can likewise be used in an embodiment of the substrate processing apparatus 10 according to the invention. The substrate support 34 has a cut-out region 35 on its front side, into which region a substrate 40 can be inserted. In this case, the substrate 40 bears in a planar manner on a closed plane 36 bounded laterally by a side wall 37 of the cut-out region 35, such that the substrate 40 cannot slip in its emplaced position on the substrate support 34.

FIG. 4 schematically shows a further possible embodiment of a substrate support 38 such as can be used in an embodiment of the substrate processing apparatus according to the invention. The substrate support 38 has hook elements 39, onto which a substrate 40 can be placed. The substrate support 38 can be used for two-sided processes, by way of example.

FIG. 5 schematically shows a diagrammatic sketch of an etching vapor supply unit 90 for a substrate processing apparatus according to the invention. In the example shown, the etching vapor supply unit 90 has a gas metering system 91 with a mass flow controller, wherein the gas metering system 91 shown has a supply line 96 for carrier gas, such as nitrogen, for example, and at least one supply line 97 for etching vapor, such as HF-containing vapor, for example. A carrier gas/etching vapor mixture arises in the gas metering system 91 and can be fed to the process chamber 20 through a line 98.

FIG. 6 schematically shows a further diagrammatic sketch of an etching vapor supply unit 90′. The etching vapor supply unit 90′ has an etching vapor generating system having a temperature-regulated space 94, in which a liquid etching substance 93, such as HF, for example, is situated. The space 94 has a supply line 96′, through which carrier gas, such as nitrogen, for example, can be conducted into the the etching substance 93. The carrier gas flows through the temperature-regulated liquid etching substance 93, as a result of which a carrier gas/etching vapor mixture forms above the etching substance 93 in the space 94 and can be passed from the space 94 to the process chamber 20 through a line 98′.

FIG. 7 schematically shows how the etching vapor supply unit 90 from FIG. 5 can be coupled to the process chamber 20. The carrier gas/etching vapor mixture or the process gas is fed to the process chamber 20 through the line 98. In the example shown, a process pressure p≦pₐₜₘ or a vacuum is set in the process chamber 20. The substrate 40 situated in the process chamber 20 is correspondingly vapor-etched at the process pressure or in the vacuum by means of the process gas fed through the line 98. In other embodiments of the present invention, a process pressure p≧pₐₜₘ can also be set in the process chamber 20, such that the vapor etching method in the process chamber 20 can be effected at atmospheric pressure or excess pressure.

In the exemplary embodiment in FIG. 7, the pressure reduction is effected by means of a vacuum pump 24 provided on a gas discharge 62 of the process chamber 20. Through the gas discharge 62, after the vapor etching process has taken place, the spent process gas can be passed via an exhaust gas removing system 63 and thus reprocessed in an ecologically appropriate manner. The outgoing air emerging from the exhaust gas removing system 63 through a gas discharge 64 is at atmospheric pressure pₐₜₘ.

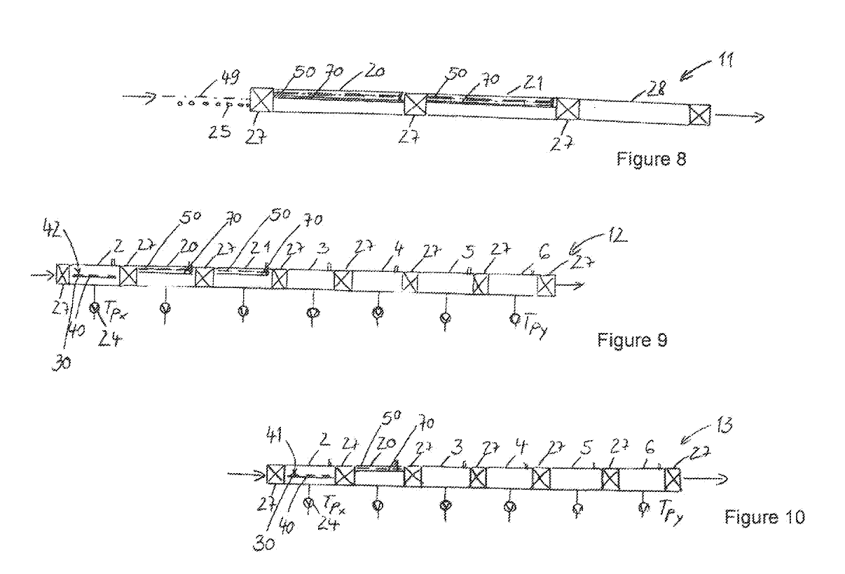

FIG. 8 schematically shows an embodiment of a substrate processing apparatus 11 according to the invention in the form of a continuous or inline apparatus having at least two process chambers 20, 21 provided according to the invention. Upstream of a gate 27 of the first process chamber 20, on rollers 25 in a carrier transport plane 49, a substrate carrier as shown in FIG. 1 is introduced into the process chamber 20. The process chamber 20 has both a plasma generating module 50 and a vapor etching module 70, by means of which, in one and the same process chamber 20, plasma treatments and also vapor etching processes can be performed on one or a plurality of substrates introduced into the process chamber 20.

The process chamber 20 is followed by a further gate 27, through which the substrates processed in the process chamber 20 are moved into a further process chamber 21 on the substrate carrier. A plasma generating module 50 and also a vapor etching module 70 are likewise integrated in the process chamber 21. Consequently, both plasma and vapor etching processes can be performed in both process chambers 20, 21. This has the advantage that, by this means, a faster throughput of substrates through the substrate processing apparatus 11 is possible and the process diversity can be increased.

The process chamber 21 is followed by a further gate 27, through which the substrates processed in the process chamber 21 can be introduced into a further process chamber 28. The further process chamber 28 can be embodied identically or similarly to the process chambers 20, 21, but can also be configured completely differently. By way of example, the process chamber 28 can be a deposition chamber for a silicon nitride deposition.

At the end of the process chamber 28 a gate 27 is once again provided, through which the substrates 40 processed in the process chamber 28 can either be introduced into a further process chamber of the substrate processing apparatus 11 or through which the processed substrates 40 can be removed from the substrate processing apparatus 11.

FIG. 9 schematically shows a further possible embodiment of a substrate processing apparatus 12 according to the invention in the form of a continuous or inline apparatus for producing solar cells. The substrate processing apparatus 12 illustrated is suitable, in particular, for the treatment of the rear side 42 of solar cell substrates. In the case of the substrate processing apparatus 12, the substrates 40 to be treated firstly pass through a gate 27 into a lock introduction chamber 2, which is coupled to a vacuum pump 24 for evacuating the lock introduction chamber 2. A process temperature Tₚₓ required for the subsequent processing is set in the lock introduction chamber 2. The substrates 40 to be treated pass through a further gate 27 into a process chamber 20, which is embodied identically or similarly to the process chamber 20 from FIG. 1 and has, in particular, a plasma generating module 50 and a vapor etching module 70. An HF vapor etching step, in which a PSG layer is etched from the substrate rear side 42, is effected in the process chamber 20. Afterward, in the process chamber 20, an emitter rear-side etching is carried out in an RIE plasma etching step using CF₄ and O₂ in order to remove the parasitic emitter from the substrate rear side 42. During the processes, the interior of the process chamber 20 is evacuated by means of a vacuum pump 24 and a process temperature T_{py} required for the subsequent processing is set.

Through a further gate 27 following the process chamber 20, the substrates 40 on the substrate carrier 30 pass into a further process chamber 21, which is embodied identically or similarly to the process chamber 20 from FIG. 1 and has, in particular, a plasma generating module 50 and a vapor etching module 70. In the process chamber 21, which can likewise be evacuated by means of a vacuum pump 24, an O₂ plasma cleaning is performed, by means of which polymer residues that can arise during the emitter rear-side etching are removed from the substrate rear side 42. Furthermore, an HF vapor etching is subsequently carried out in the process chamber 21.

Via a further gate 27, the substrates 40 thereupon pass into a lock 3, which can be evacuated by means of a vacuum pump 24 and in which the temperature of the substrates 40 can be set to approximately 400° C.

Through a further gate 27, the substrates 40 are transported into a further process chamber 4, in which an Si₃N₄ PECVD deposition is carried out on the substrate rear side 42. During the Si₃N₄ PECVD deposition, the process chamber 4 is evacuated by means of a vacuum pump 24 and the process chamber 4 is temperature-regulated to approximately 400° C. The substrates 40 can thereupon be treated further in further, downstream process chambers 5, 6.

FIG. 10 schematically shows a further possible embodiment of a substrate processing apparatus 13 according to the invention in the form of a continuous or inline apparatus for producing solar cells. The substrate processing apparatus 13 shown is suitable, in particular, for the treatment of the substrate front side 41 of solar cell substrates.

In the substrate processing apparatus 13, the substrates 40 to be processed pass, by means of a substrate carrier 30, into a lock introduction chamber 2, which, in principle, is embodied similarly to the lock introduction chamber 2 from FIG. 9. Through a further gate 27, the substrates 40 are transported into a process chamber 20, which is embodied identically or similarly to the process chamber 20 from FIG. 1. An HF vapor etching step that etches a PSG layer from the substrate front side 41 is effected in the process chamber 20. In a subsequent plasma step, the etched substrate front side 41 is oxidized. The process chamber 20 is followed, via a gate 27, by a lock 3, which is embodied identically or similarly to the lock 3 from FIG. 9 and in which the substrates 40 are heated to approximately 400° C. Afterward, the substrates 40 pass via a gate 27 into a further process chamber 4, in which an Si₃N₄ PECVD deposition is performed on the substrate front side 41. The substrates 40 can thereupon be treated further in further process chambers 5, 6 and finally be removed from the substrate processing apparatus 13.

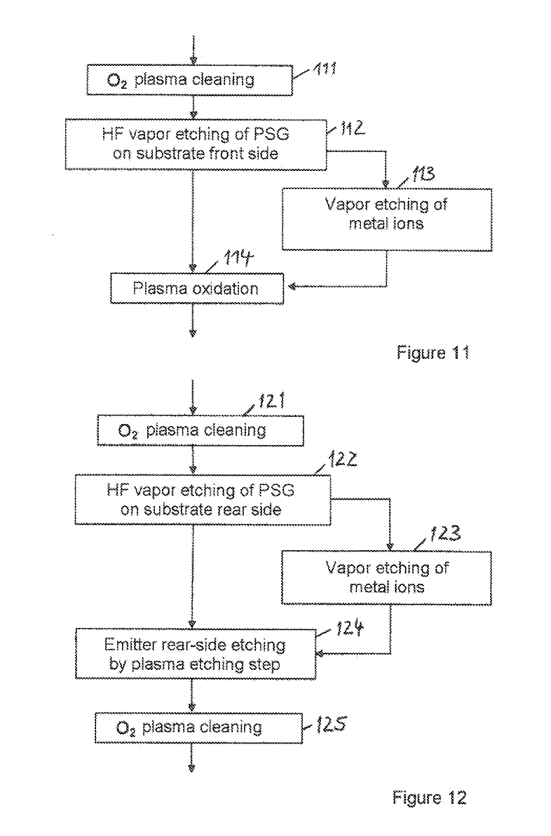

FIG. 11 schematically shows an embodiment of a substrate processing method according to the invention, which, by way of example, can be performed in the process chamber 20 from FIG. 1. The method example from FIG. 11 serves for PSG etching on a substrate front side 41 of a substrate 40 for producing solar cells.

In the step 111, firstly an O₂ plasma cleaning of the substrate front side 41 is optionally effected. In a further step 112, a vapor etching using HF-containing vapor is carried out in order to etch a PSG layer from the substrate front side 41. Optionally, in a subsequent step 113, in the same process chamber 20, a vapor etching of the substrate front side 41, for example using HF and O₃, can be carried out in order to remove metal ions from the substrate front side 41.

Either directly succeeding step 112 or after step 113, in step 114, a plasma oxidation of the substrate front side 41 is effected, in which a thin oxide layer is applied to said substrate front side, on which oxide layer, by way of example, a subsequently applied silicon nitride layer adheres particularly well.

FIG. 12 schematically shows a further possible embodiment of a substrate processing method according to the invention. The method example from FIG. 12 serves, for example, for PSG and emitter rear-side etching of solar cell substrates.

In a first method step 121 of the method from FIG. 12, an O₂ plasma cleaning of a substrate rear side 42 of a substrate 40 is optionally effected. In a subsequent step 122, an HF vapor etching of a PSG layer from the substrate rear side 42 is carried out. Optionally, by way of example, an HF and O₃ vapor etching of metal ions on the substrate rear side 42 can be effected in a subsequent step 123.

Either directly after step 122 or after step 123, in method step 124, an emitter rear-side etching using F- or Cl-containing etching gases and O₂ is carried out in a plasma etching step in the process chamber 20. Afterward, optionally an O₂ plasma cleaning of the substrate rear side 42 can be carried out again in a step 125.

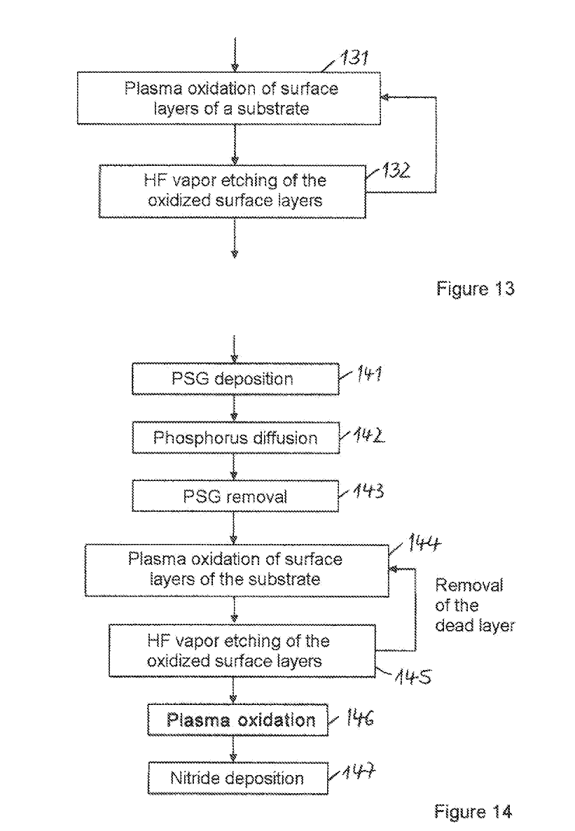

FIG. 13 schematically shows a further embodiment of a substrate processing method according to the invention, which can be used both as a cleaning method and for removing a “dead layer” on solar cell substrates. In a first method step 131, a plasma oxidation of a substrate front and/or substrate rear side 41, 42 is effected. In the plasma oxidation step 131, one or a plurality of surface layers of the substrate front and/or substrate rear side 41, 42 are oxidized, which are subsequently etched by means of HF-containing vapor in a method step 132. Steps 131 and 132 can be performed alternately a number of times.

FIG. 14 schematically shows a further embodiment of the substrate processing method according to the invention, which can be used, in particular, in the production of solar cells. Starting substrates for the method illustrated in FIG. 14 are silicon substrates which have been subjected, in a step 141, to a deposition of a PSG layer for a subsequent phosphorus diffusion 142 and in the case of which the PSG layer has subsequently been removed in a step 143.

In a first method step 144, which is performed in the process chamber 20, a plasma oxidation is effected, during which one or a plurality of surface layers of the substrate front and/or substrate rear side 41, 42 are oxidized. Afterward, in method step 145, a vapor etching using HF-containing vapor is carried out in order to remove the oxidized surface layers. The plasma oxidation step 144 and the HF vapor etching step 145 are successively carried out alternately a number of times. As a result, the so-called “dead layer” that is already present on the surface of the silicon substrates owing to the phosphorus diffusion is removed piece by piece.

A plasma oxidation is subsequently carried out in method step 146 from FIG. 14, as a result of which an oxide layer arises on the surface of the substrates 40, on which oxide layer a silicon nitride layer subsequently deposited in step 147 adheres particularly well.

FIG. 15 schematically shows a further embodiment of the substrate processing method according to the invention, which, by way of example, can be used for the surface cleaning of solar cell substrates. For this purpose, in a first method step 151, substrates 40 are subjected to an O₂ plasma cleaning and subsequently etched in a vapor etching step 152 using a vapor mixture containing HF and reactive oxygen, such as ozone, for example. By means of a suitable setting of the concentration of the reactive oxygen in the vapor mixture, either preferably an oxidation or, by means of the HF vapor, an etching of an oxide layer at the substrate surface can be effected. Thus, by way of example, by means of the method shown in FIG. 15, a “dead layer” can be removed from solar cell substrates or the surface of substrates can just simply be cleaned and an a—Si PECVD layer can subsequently be deposited in a process step 153.

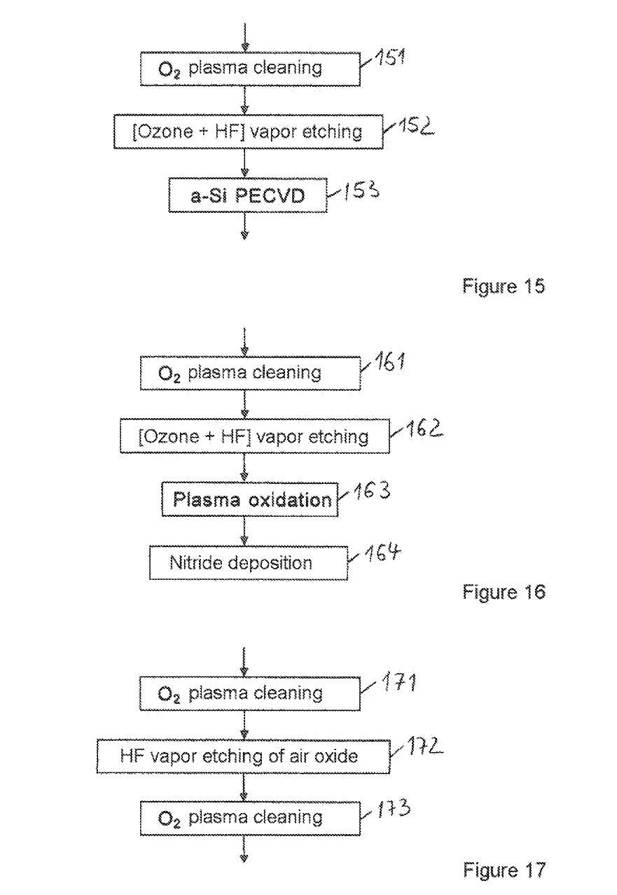

FIG. 16 schematically shows a further embodiment of the substrate processing method according to the invention, which is based on the method steps of the method from FIG. 15. In this case, an O₂ plasma cleaning is optionally carried out in a first method step 161. A vapor etching step using a vapor mixture containing HF and reactive oxygen is effected in a further method step 162. By way of example, a “dead layer” can be removed in this method step. A plasma oxidation is subsequently effected in method step 163, as a result of which, by way of example, a substrate for solar cell production is well prepared for a subsequent silicon nitride deposition in step 164.

FIG. 17 schematically shows a further embodiment of the substrate processing method according to the invention for air oxide removal, for example before an a—Si PECVD deposition step.

Firstly, an O₂ plasma cleaning is effected in an optional method step 171. In a subsequent step 172, air oxide is etched from substrates 40 in a vapor etching step using HF-containing vapor. The air oxide etching in step 172 can be effected from a substrate front side 41 and/or a substrate rear side 42.

An O₂ plasma cleaning can once again optionally be performed in a subsequent plasma step 173.

While the invention has been particularly shown and described with reference to preferred embodiments thereof, it will be understood by those skilled in the art that various changes in form and details may be made therein without departing from the spirit and scope of the invention.

1-24. (canceled)

25. A continuous substrate processing apparatus comprising:
at least one evacuatable process chamber configured to receive at least one substrate carrier having at least one substrate;
a plasma generating module;
at least one gas feed;
at least one gas discharge; and
a vapor etching module disposed in the process chamber.

26. The substrate processing apparatus as recited in claim 25, wherein the vapor etching module is an HF vapor etching module.

27. The substrate processing apparatus as recited in claim 25, further comprising an etching gas-resistant internal lining and an etching gas-resistant substrate carrier.

28. The substrate processing apparatus as recited in claim 25, wherein the vapor etching module includes a gas spray having a plurality of gas outlets distributed over an area of the process chamber.

29. The substrate processing apparatus as recited in claim 25, further comprising an etching vapor supply unit coupled to the vapor etching module.

30. The substrate processing apparatus as recited in claim 29, wherein the etching vapor supply unit includes at least one of a gas metering system and an etching vapor generating system having a temperature regulated space, the temperature-regulated space being configured to receive a liquid etching substance and to pass at least one carrier gas flow therethrough.

31. The substrate processing apparatus as recited in claim 25, wherein the plasma generating module includes at least one suppliable electrode disposed in the process chamber, the at least one suppliable electrode having a planar configuration.

32. The substrate processing apparatus as recited in claim 25, wherein the at least one substrate carrier includes at least one substrate support having a planar supporting region configured to support a circumferential region of at least one substrate.

33. The substrate processing apparatus as recited in claim 32, wherein the substrate support includes an opening within the supporting region.

34. The substrate processing apparatus as recited in claim 25, further comprising at least one internal volume reducing component disposed in the process chamber.

35. The substrate processing apparatus as recited in claim 25, wherein the substrate processing apparatus is configured to produce solar cells.

36. The substrate processing apparatus as recited in claim 25, further comprising at least one of a heating and a cooling device disposed in the process chamber or coupled to the process chamber.

37. A substrate processing method comprising:
introducing at least one substrate carrier including at least one substrate into at least one evacuatable process chamber;
generating a plasma in a plasma process using a plasma generating module in a gas or a gas mixture so as to provide at least one of a coating, etching, surface modification and cleaning of the substrate;
performing a vapor etching of the at least one substrate before, after or alternatingly with the plasma process.

38. The substrate processing method as recited in claim 37, wherein the vapor etching is performed using an HF-containing vapor.

39. The substrate processing method as recited in claim 37, wherein the vapor etching is performed so as to produce solar cells.

40. The substrate processing method as recited in claim 37, wherein the vapor etching includes an HF vapor etching step for etching PSG from a front side of the at least one substrate, and the plasma process includes plasma oxidation of one or more surface layers of the at least one substrate after the HF vapor etching step.

41. The substrate processing method as recited in claim 37, wherein the vapor etching includes an HF vapor etching step for etching PSG from a rear side of the at least one substrate, and the plasma process includes emitter rear-side etching of the at least one substrate in a plasma etching step after the HF vapor etching step.

42. The substrate processing method as recited in claim 40, wherein the vapor etching includes an additional vapor etching step using a vapor mixture including HF and O₃ for etching metal ions from the at least one substrate, the additional vapor etching step being after the HF vapor etching step.

43. The substrate processing method as recited in claim 41, wherein the vapor etching includes an additional vapor etching step using a vapor mixture including HF and O₃ for etching metal ions from the at least one substrate, the additional vapor etching step being after the HF vapor etching step.

44. The substrate processing method as recited in claim 40 wherein O₂ plasma cleaning is performed before the HF vapor etching step of the at least one substrate.

45. The substrate processing method as recited in claim 41 wherein O₂ plasma cleaning is performed after the emitter rear-side etching of the at least one substrate.

46. The substrate processing method as recited in claim 37 wherein the plasma process includes plasma oxidation of at least one surface layer of the at least one substrate and the vapor etching is performed after the plasma process is performed and includes an HF vapor etching of the at least one oxidized surface layer.

47. The substrate processing method as recited in claim 45 further comprising performing the plasma oxidation and the HF vapor etching of the oxidized surface layer more than once and alternatingly.

48. The substrate processing method as recited in claim 37 wherein an O₂ plasma cleaning is performed, and wherein the vapor etching includes an HF vapor etching step using HF-containing vapor and reactive oxygen, the HF vapor etching step being after the O₂ plasma cleaning.

49. The substrate processing method as recited in claim 37 wherein the vapor etching includes an HF vapor etching step performed so as to remove air oxide from at least one of a front side and a rear side of the at least one substrate, and wherein O₂ plasma cleaning of the at least one substrate is performed at least one of before and after the HF vapor etching step.
